(19) United States
(12) Patent Application Publication
(10) Pub. No.: US 2026/0088587 A1
(43) Pub. Date: Mar. 26, 2026

(54) Laser Current Control Method, Apparatus, and Laser Device for Suppressing Laser Relaxation Oscillations

(71) Applicants: Suzhou menovex photonics technology Co., Ltd, Suzhou (CN); Menovex Medical Technology (Shenzhen) Co., Ltd, Shenzhen (CN)

(72) Inventors: Zuyong Huang, Shenzhen (CN); Encai Ji, Shenzhen (CN); Yixiang Dai, Shenzhen (CN); Wenqiang Bao, Shenzhen (CN); Qiguo Yang, Shenzhen (CN); Jinzi Bi, Shenzhen (CN); Ke Zeng, Shenzhen (CN)

(73) Assignees: Suzhou menovex photonics technology Co., Ltd, Suzhou (CN); Menovex Medical Technology (Shenzhen) Co., Ltd, Shenzhen (CN)

(21) Appl. No.: 19/196,739

(22) Filed: May 2, 2025

Related U.S. Application Data
(63) Continuation of application No. PCT/CN2024/122638, filed on Sep. 30, 2024.

(30) Foreign Application Priority Data
Jun. 3, 2024 (CN) 202410703660.X

(51) Int. Cl. H01S 5/042

(52) U.S. Cl. CPC H01S 5/0428; H01S 5/0427

(57) ABSTRACT

The present disclosure provides a laser current control method for suppressing laser relaxation oscillations, relating to the field of laser control technologies. The method comprising: controlling a current signal with a preset waveform to be input into a laser drive circuit; the preset waveform includes a first step and a second step, where the amplitude of the first step is less than that of the second step, and the current signal of the first step triggers a laser relaxation oscillation waveform whose amplitude is less than a safety threshold; and adjusting the amplitude of the second step based on a relationship between the average laser output power and the drive current. According to the embodiments of the present disclosure, a small-step current waveform is designed to effectively suppress damage to optical components in the optical path caused by laser relaxation oscillations. The reduced pulse distortion ensures that the threshold current corresponding to different pulse frequencies exhibits linearity under the same duty cycle, eliminating the need to record threshold currents and corresponding linear equations for each duty cycle. This allows the output current to be more precisely and accurately adjusted to achieve a desired terminal average power.

### CROSS-REFERENCE TO RELATED APPLICATIONS

This application claims priority to PCT Application No. PCT/CN2024/122638, filed Sep. 30, 2024 and to Chinese Patent Application No. 202410703660.X, filed on Jun. 3, 2024, entitled “Laser Current Control Method, Apparatus, and Laser Device for Suppressing Laser Relaxation Oscillations,” the entirety of which are incorporated herein by reference.

### FIELD OF THE INVENTION

The present disclosure relates to the field of laser control technologies, and more particularly to a method, apparatus, and laser device for controlling laser current to suppress relaxation oscillations.

### BACKGROUND OF THE INVENTION

With the advancement of technology, lasers have become increasingly essential in both industrial products and medical equipment for processing and treatment applications. In high-power industrial laser systems, fluctuations in power output caused by thermal drift, current ripple, or frequency jitter are often negligible. However, in medical devices, where the laser is applied directly to the patient and the average output power is typically low (commonly less than or equal to 70 W), the requirements for precision and stability of the average laser power are significantly more stringent than those of industrial systems. This creates a need for a power correction or compensation algorithm that offers fine adjustment granularity and stable control performance.

According to factory calibration reports for laser diodes (LDs), when the drive current exceeds a certain threshold value I1, the relationship between the drive current and the laser output power of the LD can be approximated by a linear equation. This linear behavior generally holds across a range of pulse width modulation (PWM) duty cycles. Continuous-wave (CW) output may also be regarded as a special case of PWM with a 100% duty cycle.
(1) Theoretically, the prior art provides a curve describing the relationship between the drive current and peak laser power when the PWM duty cycle is 100%. This linear relationship is then extended to current waveforms with duty cycles less than 100%, which are also expected to conform to the same linear behavior. While this theoretical assumption is generally valid, in practical analog electronic circuits, the electrical signal applied across the laser diode is not an ideal square wave, but rather transforms into a waveform resembling a trapezoid or triangle. As a result, experimental test data reveal that, even at the same duty cycle, the slope of the linear relationship differs considerably at different frequencies.
(2) Based on the above limitation, if a medical laser device is required to operate across a frequency range from 1 to 2400 Hz, then an excessive number of linear equations would need to be defined. This results in a substantial workload for calibration and adjustment, making it unsuitable for mass production of such devices.
(3) In addition, existing laser power output control algorithms do not address the issue of laser relaxation oscillations. As the required peak power increases, if the current signal does not effectively suppress relaxation oscillations, it can easily lead to damage in the optical path of the laser system. This is because relaxation oscillations cause short-duration high-peak-power laser pulses during each emission cycle, which may exceed the tolerance limits of certain optical components and result in their failure.

### SUMMARY OF THE INVENTION

To address the above issue, the present disclosure provides a laser current control method for suppressing laser relaxation oscillations. The method comprises:
controlling a current signal with a preset waveform to be input to a laser drive circuit; wherein the preset waveform comprises a first step and a second step, an amplitude of the first step being smaller than an amplitude of the second step, and a laser relaxation oscillation waveform triggered by the current signal of the first step having an amplitude less than a safety threshold;
adjusting the amplitude of the second step based on a relationship between average laser output power and drive current;
wherein the current signal of the second step is processed by the laser drive circuit to obtain the drive current; and
wherein the relationship between the average laser output power and the drive current is determined by a peak power corresponding to the first step, a duty cycle corresponding to the first step, a maximum drive current, a threshold current, a peak power corresponding to the maximum drive current, and a duty cycle corresponding to the second step.

Optionally, the relationship between the average laser output power and the drive current signal is as follows:

$${P}_{out} = {P}_{p \_ It 0} * ( {t}_{0} * f ) + [ ( {I}_{out} - {I}_{th} ) / ( {I}_{max} - {I}_{th} ) ] * ( {P}_{pmax} * D )$$

wherein Pₒᵤₜ is the average laser output power; P_{p_It0} is the peak power corresponding to the first step; t₀*f is the duty cycle corresponding to the first step; t₀ is the width of the first step; Iₒᵤₜ is the drive current; Iₘₐₓ is the maximum drive current; Iₜₕ is the threshold current; Pₚₘₐₓ is the peak laser power corresponding to the maximum drive current; D is the duty cycle corresponding to the second step; and P_{aIth} is the average power corresponding to the threshold current.

Optionally, the relationship between the average laser output power and the drive current signal is as follows:

$${I}_{out} = ( ( ( {P}_{out} - ( {P}_{p \_ It 0} * ( {t}_{0} * f ) ) ) - {P}_{aIth} ) / ( {P}_{pmax} * D - {P}_{aIth} ) ) ( {I}_{max} - {I}_{th} ) + {I}_{th}$$

wherein Pₒᵤₜ is the average laser output power; P_{p_It0} is the peak power corresponding to the first step; t₀*f is the duty cycle corresponding to the first step; t₀ is the width of the first step; Iₒᵤₜ is the drive current; Iₘₐₓ is the maximum drive current; Iₜₕ is the threshold current; Pₚₘₐₓ is the peak laser power corresponding to the maximum drive current; D is the duty cycle corresponding to the second step; and P_{aIth} is the average power corresponding to the threshold current.

Optionally, the threshold current is linearly and positively correlated with the laser pulse frequency.

Optionally, the relationship between the threshold current and the laser pulse frequency is as follows:

$${I}_{th} = Af + B$$

wherein f is the laser pulse frequency, and A and B are coefficients.

Optionally, tuning the amplitude and the width of the first step based on a tolerance value of components in the laser drive circuit.

Optionally, the derivation process of the relationship between the average laser output power and the drive current signal is as follows:

$$Since {P}_{pset} : {P}_{pmax} = ( {I}_{out} - {I}_{t h} ) : ( {I}_{max} - {I}_{t h} ) \qquad Equation$$

$$then {I}_{out} = ( {P}_{pset} / {P}_{pmax} ) * ( {I}_{max} - {I}_{t h} ) + {I}_{t h}$$

wherein Pₚₛₑₜ is the peak power;
the average laser output power Pₒᵤₜ is equal to an average power Pₜ₀ of the first step plus an average power P_{Iout} to be output, thus:

$${P}_{out} = {P}_{t 0} + {P}_{Iout} \qquad Equation$$

the average power P_{Iout} to be output is equal to a peak power Pₚₛₑₜ corresponding to Iₒᵤₜ multiplied by the duty cycle D, thus:

$${P}_{Iout} = {P}_{p s e t} * D \qquad Equation$$

from Equations \textcircled{1} and \textcircled{3}, it follows that:

$${I}_{out} = [ {P}_{Iout} / ( {P}_{pmax} * D ) ] * ( {I}_{max} - {I}_{t h} ) + {I}_{t h} \qquad Equation$$

$${P}_{out} = {P}_{t 0} + [ ( {I}_{out} - {I}_{t h} ) / ( {I}_{max} - {I}_{t h} ) ] * ( {P}_{pmax} * D ) \qquad Equation$$

the average power P_{t0_cw} in continuous mode corresponding to the current Iₜ₀ of the first step is:

$${P}_{t 0\_ cw} = {P}_{p \_ It 0}$$

the width of the first step is to, and its duty cycle is:

$${D}_{t 0} = {t}_{0} * f$$

the average power of the first step is:

$${P}_{t 0} = {P}_{p \_ It 0} * {D}_{t 0} = {P}_{p \_ It 0} * ( {t}_{0} * f )$$

thus, Equation \textcircled{5} is transformed into:

$${P}_{out} = {P}_{p \_ It 0} * ( {t}_{0} * f ) + [ ( {I}_{out} - {I}_{t h} ) / ( {I}_{max} - {I}_{t h} ) ] * ( {P}_{pmax} * D ) . \qquad Equation$$

Optionally, the derivation process of the relationship between the average laser output power and the drive current signal is as follows:

$$Since ( {P}_{pset} - {P}_{Ith} ) : ( {P}_{pmax} - {P}_{Ith} ) = ( {I}_{out} - {I}_{th} ) : ( {I}_{max} - {I}_{th} ) \qquad Equation 1$$

$$then {I}_{out} = ( {P}_{pset} - {P}_{Ith} ) ( {I}_{max} - {I}_{th} ) / ( {P}_{pmax} - {P}_{Ith} ) + {I}_{th}$$

wherein Pₚₛₑₜ is the peak power;
the relationship between the peak power P_{Ith} and the corresponding average power P_{aIth} is as follows:

$${P}_{Ith} = {P}_{aIth} / D \qquad Equation 2$$

D is the duty cycle, and P_{Ith} is the peak power corresponding to the threshold current under the duty cycle D;
if the influence of P_{aIth} is ignored, the equation is equivalent to:

$${I}_{out} = ( {P}_{pset} ) ( {I}_{max} - {I}_{th} ) / ( {P}_{pmax} ) + {I}_{th}$$

the average laser output power Pₒᵤₜ equals the average power Pₜ₀ of the small step plus the average power Pₛₑₜ output by the current waveform, thus:

$${P}_{out} = {P}_{t 0} + {P}_{Iout} \qquad Equation 3$$

moreover, since the required average output power P_{Iout} equals the peak power Pₚₛₑₜ corresponding to Iₒᵤₜ multiplied by the duty cycle D, it follows that:

$${P}_{Iout} = {P}_{pset} * D \qquad Equation 4$$

from Equations 1, 2, and 4, it follows that:

$${I}_{out} = [ ( {P}_{Iout} - {P}_{a I t h} ) / ( {P}_{p max} * D - {P}_{a I t h} ) ] * ( {I}_{max} - {I}_{t h} ) + {I}_{t h} \qquad Equation 5$$

$${I}_{out} = \{ [ ( {P}_{out} - {P}_{t 0} ) - {P}_{a I t h} ] / ( {P}_{p max} * D - {P}_{a I t h} ) \} * ( {I}_{max} - {I}_{t h} ) + {I}_{t h} \qquad Equation 6$$

the average power P_{t0_cw} in continuous mode corresponding to the first-step current Iₜ₀ is:

$${P}_{t 0\_ cw} = {P}_{p\_It 0}$$

the width of the first step is to, and its duty cycle is:

$${D}_{t 0} = {t}_{0} / T = {t}_{0} * f$$

the average power of the first step is:

$${P}_{t 0} = {P}_{p \_ It 0} * {D}_{t 0} = {P}_{p \_ It 0} * ( {t}_{0} * f )$$

therefore, Equation 6 is transformed into:

$${I}_{out} = [ ( {P}_{out} - ( {P}_{p \_ It 0} * ( {t}_{0} * f ) ) - {P}_{a I t h} ) / ( {P}_{p max} * D - {P}_{a I t h} ) ] * ( {I}_{max} - {I}_{t h} ) + {I}_{t h} . \qquad Equation 7$$

Optionally, a third step is further provided between the first step and the second step, wherein the amplitude of the third step is less than that of the second step and greater than that of the first step.

An embodiment of the present disclosure provides a laser current control apparatus for suppressing laser relaxation oscillations, comprising:
a waveform output module configured to control a current signal with a preset waveform to be input to a laser drive circuit;
wherein the preset waveform comprises a first step and a second step, the amplitude of the first step being smaller than an amplitude of the second step, and a laser relaxation oscillation waveform triggered by the current signal of the first step having an amplitude less than a safety threshold;
a regulation module configured to adjust the amplitude of the second step based on the relationship between average laser output power and the drive current;
wherein the current signal of the second step is processed by the laser drive circuit to obtain the drive current; and
wherein the relationship between the average laser output power and the drive current is determined by a peak power corresponding to the first step, a duty cycle corresponding to the first step, the maximum drive current, the threshold current, the peak laser power corresponding to the maximum drive current, and the duty cycle corresponding to the second step.

Optionally, the relationship between the average laser output power and the drive current signal is as follows:

$${P}_{out} = {P}_{p \_ It 0} * ( {t}_{0} * f ) + [ ( {I}_{out} - {I}_{t h} ) / ( {I}_{max} - {I}_{t h} ) ] * ( {P}_{p max} * D )$$

wherein Pₒᵤₜ is the average laser output power; P_{p_It0} is the peak power corresponding to the first step; t₀*f is the duty cycle corresponding to the first step; t₀ is the width of the first step; Iₒᵤₜ is the drive current; Iₘₐₓ is the maximum drive current; Iₜₕ is the threshold current; Pₚₘₐₓ is the peak laser power corresponding to the maximum drive current; and D is the duty cycle corresponding to the second step.

Optionally, the threshold current is linearly and positively correlated with the laser pulse frequency.

An embodiment of the present disclosure provides a laser device, comprising a computer-readable storage medium storing a computer program and a processor, wherein the computer program, when read and executed by the processor, is configured to implement the above-described laser current control method for suppressing laser relaxation oscillations.

The laser current control method, apparatus, and laser device for suppressing laser relaxation oscillations provided in this embodiment are designed with a small-step current waveform, which effectively suppresses damage to optical components in the optical path caused by laser relaxation oscillations. The small-step current waveform effectively reduces the distortion of the effective current pulse waveform, resulting in a more rectangular laser output waveform. With reduced pulse distortion, the threshold current corresponding to different pulse frequencies under the same duty cycle exhibits a linear relationship, eliminating the need to record the threshold current and linear equation for each duty cycle. The mathematical relationship between the average output power of the laser terminal and the adjusted current takes into account the average power contribution of the small step, allowing for more accurate and precise adjustment of the output current to achieve the desired terminal average power.

### BRIEF DESCRIPTION OF THE DRAWINGS

To more clearly illustrate the technical solutions of the embodiments of the present disclosure or the prior art, a brief description of the drawings required for describing the embodiments or the prior art is provided below. It should be understood that the following drawings merely depict embodiments of the present disclosure. A person skilled in the art may also derive other drawings from the provided ones without any inventive effort.

FIG. 1 illustrates the relationship between the drive current and the laser output power of a conventional laser diode.

FIG. 2 is a schematic flowchart of a laser current control method for suppressing laser relaxation oscillations provided in an embodiment of the present disclosure.

FIG. 3 is a schematic diagram of an initial current waveform provided in an embodiment of the present disclosure.

FIG. 4 is a schematic diagram of an amplified current waveform provided in an embodiment of the present disclosure.

FIG. 5 is a schematic diagram of a current waveform provided in an embodiment of the present disclosure.

FIG. 6 is another schematic diagram of a current waveform provided in an embodiment of the present disclosure.

FIG. 7 is a schematic structural diagram of a laser current control apparatus for suppressing laser relaxation oscillations provided in an embodiment of the present disclosure.

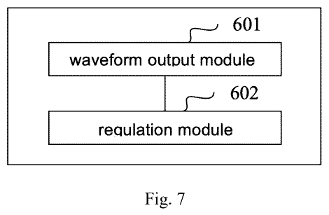

### DETAILED DESCRIPTION OF THE EMBODIMENTS

To make the objectives, features, and advantages of the present disclosure more clearly understood, detailed descriptions of specific embodiments of the present disclosure are provided below in conjunction with the accompanying drawings. It should be understood that the specific embodiments described herein are merely intended to illustrate the present disclosure and should not be construed as limiting.

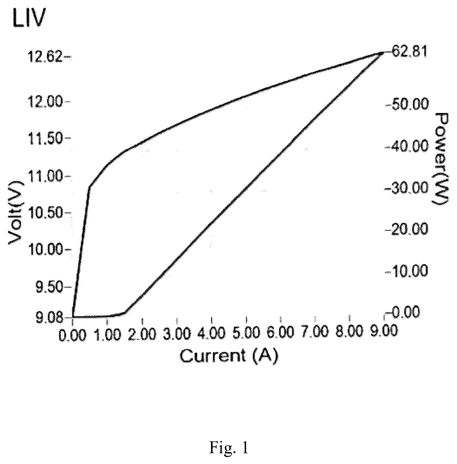

FIG. 1 illustrates the relationship between the drive current and the laser output power of a conventional laser diode (LD). In FIG. 1, the lower portion shows the current-peak laser power curve, and the upper portion shows the current-voltage curve.

According to the factory calibration report for the laser diode, when the drive current exceeds a certain value I₁, the relationship between the drive current and the laser output curve of the diode satisfies a linear equation. This linear pattern holds for almost every PWM current output with different duty cycles. The continuous current output mode can also be regarded as a PWM current output with a 100% duty cycle.

A common power correction algorithm divides the current range based on the electro-optical conversion efficiency. For example, as shown in the curve in FIG. 1, the current range can be roughly divided into two segments according to the electro-optical conversion efficiency: 1 A<I₁≤1.5 A and 1.5 A<I₂≤9.00 A.

According to linear equations, two separate linear functions can be derived, expressed as: y₁=K₁x₁+b₁ and y₂=k₂x₂+b₂.

At different frequencies, even when the duty cycle D remains the same, the pulse width t will vary. Therefore, each frequency should correspond to its own pair of linear equations.

An embodiment of the present disclosure addresses the drawback (1) of the prior art, where the electrical signal driving both ends of the laser diode (LD) is prone to distortion into a trapezoidal or triangular waveform in analog electronic circuits, by designing a current control method to reduce such waveform distortion.

To address drawback (2), the present disclosure establishes a relationship between frequency and the current offset bₓ of different equations as bₓ=Af+B, thus avoiding the need to record numerous slopes and offsets for each equation.

Relaxation oscillation is an inevitable phenomenon during the process of establishing laser equilibrium. However, it can be constrained within a safe amplitude. Therefore, the present disclosure provides a current output control algorithm that limits the effects of relaxation oscillation within a range tolerable by the laser optical path, thereby preventing damage to the optical components in the path.

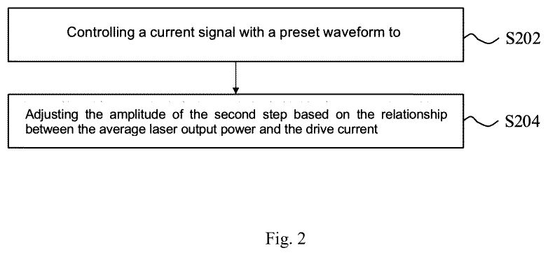

FIG. 2 illustrates a flow diagram of a laser current control method for suppressing laser relaxation oscillations provided in an embodiment of the present disclosure. The method includes:
S202: controlling a current signal with a preset waveform to be input into the laser drive circuit.

The laser drive circuit may be connected to a laser diode. After the preset waveform current signal is input into the laser drive circuit, a drive current for the laser diode is output.

In this embodiment, the preset waveform may include a first step and a second step, where the amplitude of the first step is less than that of the second step. By way of example, the preset waveform may adopt a stepped waveform structure. The current signal of the first step induces a laser relaxation oscillation whose amplitude is less than a safety threshold. This safety threshold is affected by the parameters of components in the laser drive circuit, and a relaxation oscillation with an amplitude below this threshold will not damage the components in the optical path.

Since the current signal is amplified in the laser drive circuit before being input into the laser diode, the electrical signal undergoes distortion after amplification, appearing in a shape resembling a trapezoid or similar waveform.

In this embodiment, a first-step current is added before the current pulse signal calculated based on existing theoretical formulas. This smaller current is used to quickly charge the filter circuit components such as capacitors and resistors in the drive circuit, thereby reducing waveform distortion of the effective electrical pulse and obtaining a laser pulse signal that more closely matches the theoretical calculation.

In this embodiment, a current control algorithm is used to limit the damage caused by relaxation oscillations to the optical components in the laser optical path within an acceptable range, rather than eliminating the oscillations entirely.

As the drive current increases, the peak power generated by the laser diode also increases, which in turn leads to higher relaxation oscillation waveforms during the initial phase of laser equilibrium establishment. If the waveform exceeds a certain threshold, it may damage the optical components. Therefore, in this embodiment, a smaller first-step current is first applied to allow the laser to establish equilibrium. Then, the large current corresponding to the effective PWM pulse is applied. In this way, when the large current is delivered to the laser diode, the laser equilibrium has already been largely established, and the subsequent large current will not induce significant relaxation oscillations. Meanwhile, the relaxation oscillations caused by the preceding small-step current have relatively low amplitude and remain within the tolerance range of the optical components in the optical path, thereby effectively suppressing damage to all optical components caused by relaxation oscillations.

In this embodiment, the amplitude and width of the aforementioned first step can be determined through tuning based on the tolerance values of the components in the laser drive circuit.

It should be noted that, if needed, a third step may be provided between the first step and the second step, wherein the amplitude of the third step is less than that of the second step and greater than that of the first step.

Based on the above, the small-step current waveform effectively reduces the distortion of the effective current pulse waveform, resulting in a more rectangular laser output waveform. As a result, the average laser power more closely approaches the theoretically calculated value. With reduced pulse distortion, under the same duty cycle, the threshold current Iₜₕ corresponding to different pulse frequencies exhibits a linear relationship. The threshold current is linearly and positively correlated with the laser pulse frequency. By statistically analyzing the data of Iₜₕ and f, the relationship between the threshold current and the laser pulse frequency can be obtained as follows:

$${I}_{t h} = A f + B$$

where f is the laser pulse frequency, and A and B are coefficients.

As a result, it is no longer necessary, as in the prior art, to record the threshold current Iₜₕ corresponding to each frequency for every duty cycle.
S204: adjusting the amplitude of the second step based on the relationship between the average laser output power and the drive current.

The current signal of the second step is processed by the laser drive circuit to generate the drive current. The relationship between the average laser output power and the drive current is determined by the peak power corresponding to the first step, the duty cycle corresponding to the first step, the maximum drive current, the threshold current, the peak laser power corresponding to the maximum drive current, and the duty cycle corresponding to the second step.

In this embodiment, the mathematical relationship between the average output power of the laser terminal and the adjusted current takes into account the average power contribution of the small step, enabling more accurate and precise adjustment of the output current to achieve the desired average power.

Optionally, the relationship between the average laser output power and the drive current signal is as follows:

$${P}_{out} = {P}_{p \_ It 0} * ( {t}_{0} * f ) + ( {I}_{out} / ( ( {I}_{max} - {I}_{t h} ) + {I}_{t h} ) ) * ( {P}_{p max} * D )$$

where Pₒᵤₜ is the average laser output power, P_{p_It0} is the peak power corresponding to the first step, t₀*f is the duty cycle corresponding to the first step, t₀ is the width (or duration) of the first step, Iₒᵤₜ is the drive current, Iₘₐₓ is the maximum drive current, Iₜₕ is the threshold current, Pₚₘₐₓ is the peak laser power corresponding to the maximum drive current, and D is the duty cycle corresponding to the second step.

The laser current control method for suppressing laser relaxation oscillations provided in this embodiment is designed with a small-step current waveform, which effectively suppresses damage to optical components in the optical path caused by laser relaxation oscillations. The small-step current waveform effectively reduces distortion in the effective current pulse waveform, resulting in a more rectangular laser output waveform. With reduced pulse distortion, the threshold current corresponding to different pulse frequencies under the same duty cycle exhibits a linear relationship, eliminating the need to record the threshold current and linear equation for each duty cycle. The mathematical relationship between the average output power of the laser terminal and the adjusted current takes into account the average power of the small step, thereby enabling more accurate and precise adjustment of the output current to achieve the desired terminal average power.

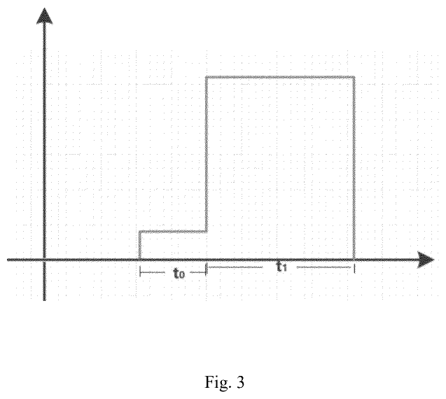

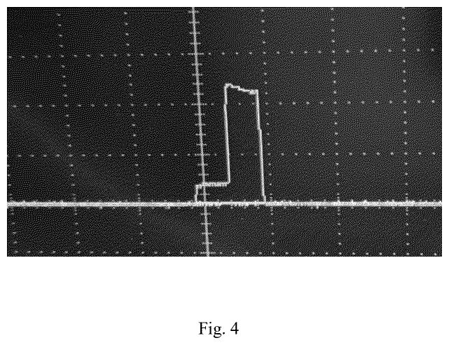

The specific implementation of the current drive control method is described as follows.
An initial current signal waveform is output under the control of a microcontroller unit (MCU). FIG. 3 illustrates a schematic diagram of the initial current waveform. As shown in FIG. 3, the current signal waveform includes a first step to and a second step t₁. The initial current is then amplified and flows into the laser diode, resulting in the amplified current waveform as shown in FIG. 4.
The presence of the to current waveform significantly ensures the integrity of the PWM output current waveform during the t₁ stage by reducing waveform distortion.

The analog electronic circuit principle of the current drive algorithm is described as follows.
Before the MCU controls the initial current to flow into the LD, the weak current needs to be amplified into a strong current, which typically requires passing through a filter circuit composed of capacitors and resistors. As a result, the initial square-wave electrical signal becomes distorted into a waveform resembling a trapezoid after amplification. After the electrical signal is distorted, the theoretically expected optical signal converted from the electrical signal is reduced, resulting in significant deviations in the calculation formulas used in the prior art.

In this embodiment, a small-step current corresponding to time “to” is added before the current pulse signal calculated based on existing theoretical formulas. This small current rapidly charges the filter circuit comprising capacitive and resistive components, thereby reducing the waveform distortion of the effective pulse during the “t₁” period and producing a laser pulse signal that more closely approximates the theoretically calculated value.

The principle of suppressing damage caused by relaxation oscillations is described as follows.

Relaxation oscillation is a phenomenon that inevitably occurs during the initial phase of laser equilibrium establishment. In this embodiment, a current control algorithm is employed to limit the impact of relaxation oscillations on the optical components in the laser optical path to an acceptable range, rather than eliminating the phenomenon altogether.

As the drive current increases, the peak power generated by the laser diode also increases. Consequently, the relaxation oscillation waveform that occurs during the initial phase of equilibrium becomes more pronounced. If it exceeds a certain level, it may damage optical components. Therefore, this embodiment first applies a small-step current “to” to allow the laser to establish equilibrium. Subsequently, a high-level current corresponding to the effective PWM pulse period “t₁” is output. Since the laser equilibrium has already been substantially established before the high current is applied, the subsequent drive current will not trigger significant relaxation oscillations. The relaxation oscillations induced by the preceding small-step current have relatively low amplitude and remain within the tolerance range of the optical components in the optical path, thereby effectively suppressing damage caused by relaxation oscillations to all optical elements in the laser path.

Empirical data demonstrates that the circuit used to drive the laser diode may vary. Accordingly, for different laser diode models, the small-step current “to” must be tuned in conjunction with the tolerance levels of the optical components in the optical path. Through actual circuit tuning, an appropriate width and amplitude of the current step can be determined. Once the width and amplitude of this small-step current are fixed, they can be applied uniformly across all frequencies and duty cycles within the same laser device.

The derivation of the current-average power relationship for enhancing the suppression of relaxation oscillation damage is as follows:

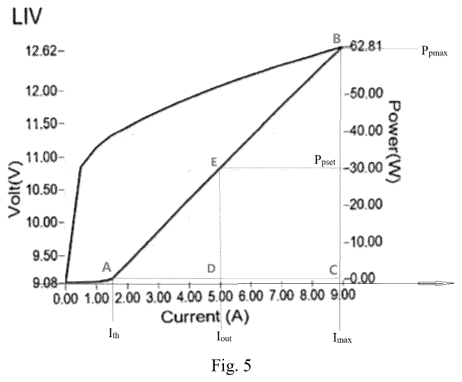

According to the prior art, a curve relationship exists between the peak power Pₚ and the drive current Iₒᵤₜ. By drawing auxiliary lines along the curve, a current waveform diagram as shown in FIG. 5 can be obtained.

$$∵ BC ⊥ A C , E D ⊥ A C , ∴ ED // BC Also , ∵ ∠ EAD = ∠ BAC ∠ AED = ∠ ABC ∠ ADE = ∠ ACB ∴ Δ EAD \sim Δ BAC \\ ∴ ED : BC = AD : AC \\ ∴ {P}_{p s e t} : {P}_{pmax} = ( {I}_{out} - {I}_{t h} ) : ( {I}_{max} - {I}_{t h} ) Therefore , {I}_{out} = ( {P}_{p s e t} / {P}_{pmax} ) * ( {I}_{max} - {I}_{t h} ) + {I}_{t h} \qquad Equation$$

Where Pₚₛₑₜ is the peak power.

The relationship between average power and output current is as follows.

The average laser output power Pₒᵤₜ is equal to the sum of the average power Pₜ₀ of the small step and the required average power P_{Iout}, thus:

$${P}_{out} = {P}_{t 0} + {P}_{Iout} \qquad Equation$$

Since the required average power P_{Iout} is equal to the peak power Pₚₛₑₜ corresponding to Iₒᵤₜ multiplied by the duty cycle D, that is, by adjusting the current corresponding to the effective current duration t₁, a peak laser power Pₚₛₑₜ can be obtained. The peak power multiplied by the duty cycle equals the required average output power P_{Iout}, thus:

$${P}_{Iout} = {P}_{p s e t} * D \qquad Equation$$

From Equations \textcircled{1} and \textcircled{3}, it follows that:

$${I}_{out} = [ {P}_{Iout} / ( {P}_{p max} * D ) ] * ( {I}_{max} - {I}_{t h} ) + {I}_{t h} \qquad Equation$$

According to the principle of similar triangles, Iₜₕ corresponds to the point at which the laser diode just begins to emit light, and this value is fixed. Alternatively, Iₜₕ may be set to a slightly higher value, in which case the intermediate term in the proportional relationship derived from the similar triangles needs to be appropriately adjusted.

The maximum output current Iₘₐₓ necessarily corresponds to the maximum peak laser power Pₚₘₐₓ, and thus Pₚₘₐₓ and Iₘₐₓ are fixed and known values. Moreover, since the duty cycle D of the output current waveform is also known, the required output current Iₒᵤₜ to be delivered by the MCU can be calculated based on the desired average output power P_{Iout}.

According to Equation \textcircled{2}, there is a difference between the actual laser power output at the terminal of the laser device and the average laser power calculated based on the adjusted drive current, which corresponds to the average power Pₜ₀ of the small step. Since the current value and duration to of the small step designed to suppress relaxation oscillations are fixed through circuit tuning (specifically, by adjusting the current magnitude and to t₀ ensure that the relaxation oscillation waveform remains within the tolerance limits of the optical components in the optical path), Pₜ₀ is a constant value. Therefore, once Pₜ₀ is determined, the relationship between the adjusted drive current Iₒᵤₜ and the average laser output power Pₒᵤₜ at the laser terminal can be obtained as follows:

$${P}_{out} = {P}_{t 0} + [ ( {I}_{out} - {I}_{t h} ) / ( {I}_{max} - {I}_{t h} ) ] * ( {P}_{pmax} * D ) \qquad Equation$$

The method for calculating the average power corresponding to the small step with duration t₀ is described below.

As described above, the width to of the small-step current and the amplitude Iₜ₀ of the small-step current are determined. At this point, by outputting a continuous current of Iₜ₀ through actual measurement and referring to the current-to-peak-power curve provided by the LD manufacturer, the peak power P_{p_It0} corresponding to Iₜ₀ can be obtained. Since the continuous output is equivalent to a PWM waveform with a 100% duty cycle, the average power P_{t0_cw} corresponding to Iₜ₀ in continuous mode is:

$${P}_{t 0 \_ cw} = {P}_{p \_ It 0}$$

Since the width of the small step is to, to may also be regarded as a pulse waveform output under a certain duty cycle at a frequency f, with the corresponding duty cycle being:

$${D}_{t 0} = {t}_{0} * f$$

In the PWM mode, the average output power of the laser is defined as the product of the peak power and the duty cycle. Accordingly, the average power of the small step is expressed as:

$${P}_{t 0} = {P}_{p \_ It 0} * {D}_{t 0} = {P}_{p \_ It 0} * ( {t}_{0} * f )$$

Since P_{p_It0} can be obtained based on Iₜ₀, and t₀ is known through tuning, both are constants, so Pₜ₀ is also a constant.

Therefore, Equation 5 can be rewritten as:

$${P}_{out} = {P}_{p \_ It 0} * ( {t}_{0} * f ) + [ ( {I}_{out} - {I}_{t h} ) / ( {I}_{max} - {I}_{t h} ) ] * ( {P}_{pmax} * D ) \qquad Equation$$

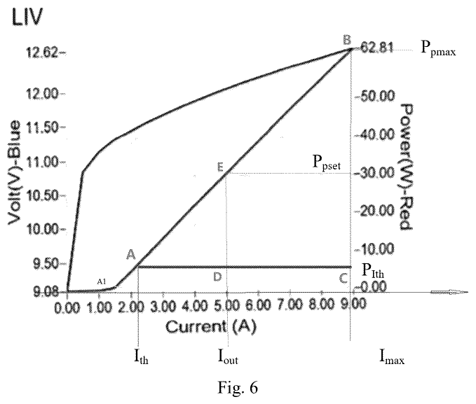

Compared with the current waveform illustrated in FIG. 5, the threshold current Iₜₕ in the current waveform illustrated in FIG. 6 is larger. Based on the current waveform shown in FIG. 6, the derivation of the current-average power relationship is as follows.

$$∵ BC ⊥ A C , E D ⊥ A C , ∴ ED // BC Also ∵ ∠ EAD = ∠ BAC ∠ AED = ∠ ABC ∠ ADE = ∠ ACB ∴ Δ EAD \sim Δ BAC \\ ∴ ED : BC = AD : AC \\ ∴ ( {P}_{p s e t} - {P}_{Ith} ) : ( {P}_{pmax} - {P}_{Ith} ) = ( {I}_{out} - {I}_{t h} ) : ( {I}_{max} - {I}_{t h} ) ∴ {I}_{out} = ( {P}_{p s e t} - {P}_{Ith} ) ( {I}_{max} - {I}_{t h} ) / ( {P}_{pmax} - {P}_{Ith} ) + {I}_{t h} \qquad Equation 1$$

Therefore, during power correction, it is only necessary to identify the corresponding segmented values of Iₘₐₓ and Iₜₕ, as well as Pₚₘₐₓ, for each frequency range. Based on the Pₚₛₑₜ set on the display, the required current can then be calculated. The peak power P_{aIth} and the corresponding average power P_{aIth} at duty cycle D satisfy the following relationship:

$${P}_{Ith} = {P}_{aIth} / D \qquad Equation 2$$

where D is the duty cycle, P_{aIth} is the average power, and P_{Ith} is the peak power corresponding to Iₜₕ at duty cycle D.

According to the current-peak power curve derived from the above formulas, if Iₜₕ is selected as 1.5 A, the corresponding P_{Ith} is equal to 0. In this case, the influence of P_{Ith} in Equation 1 can be neglected, and Equation 1 is effectively equivalent to:

$${I}_{out} = ( {P}_{p s e t} ) ( {I}_{max} - {I}_{t h} ) / ( {P}_{pmax} ) + {I}_{t h}$$

According to actual requirements, a suitable peak power point (Iₜₕ, P_{Ith}) may be selected as a starting point.

The average laser output power Pₒᵤₜ is equal to the average power Pₜ₀ of the small step plus the average power Pₛₑₜ output by the current waveform, and thus:

$${P}_{out} = {P}_{t 0} + {P}_{Iout} \qquad Equation 3$$

Since the average power P_{Iout} to be output is equal to the peak power Pₚₛₑₜ corresponding to Iₒᵤₜ multiplied by the duty cycle D, i.e., by adjusting the current corresponding to the effective pulse width t₁, a laser peak power Pₚₛₑₜ can be obtained, and the peak power multiplied by the duty cycle yields the corresponding average power P_{Iout}, so:

$${P}_{Iout} = {P}_{pset} * D \qquad Equation 4$$

Also, ∵ Equation 1 [symbol] 2 [symbol] 4,

$$∴ {I}_{out} = [ ( {P}_{Iout} - {P}_{a I t h} ) / ( {P}_{pmax} * D - {P}_{a I t h} ) ] * ( {I}_{max} - {I}_{t h} ) + {I}_{t h} \qquad Equation 5$$

According to the principle of similar triangles, Iₜₕ may be taken as the value at which the laser just begins to emit light (i.e., when the laser peak power approaches 0 W). This value is fixed according to the model of the laser pump source. Alternatively, based on the average power range of the laser, a larger value for It may be selected to define a suitable (Iₜₕ, P_{Ith}) point. For example, if the average power range of the laser is 0.5 W to 20 W, P_{Ith} may be selected as 0.5 W, and P_{Ith} can then be calculated as P_{Ith}=P_{aIth}/D. Based on Equation 1, Equation 4 becomes:

$${I}_{out} = [ ( {P}_{Iout} - 0 \text{.5} ) / ( {P}_{pmax} * D - 0.5 ) ] * ( {I}_{max} - {I}_{t h} ) + {I}_{t h}$$

Since the maximum output current Iₘₐₓ necessarily corresponds to the maximum laser peak power Pₚₘₐₓ, both Pₚₘₐₓ and Iₘₐₓ are fixed known values. In addition, as the duty cycle of the output current waveform is known, the required output current Iₒᵤₜ from the MCU can be calculated based on the desired average power P_{Iout}.

As shown in Equation 3, the average output power of the laser terminal differs from the average output power obtained by adjusting the current by a fixed average power Pₜ₀ corresponding to the small step. Since the current value and duration to of the small step for suppressing relaxation oscillation-induced damage are fixed through circuit tuning (i.e., by adjusting the current magnitude and duration to such that the relaxation oscillation waveform does not exceed the tolerance of the optical components in the optical path), Pₜ₀ is a constant value. Therefore, once Pₜ₀ is determined, the relationship between the adjusted output current Iₒᵤₜ and the average output power Pₒᵤₜ at the laser terminal can be expressed as follows:

$${I}_{out} = ( ( ( {P}_{out} - {P}_{t 0} ) - {P}_{a I t h} ) / ( {P}_{pmax} * D - {P}_{a I t h} ) ) ( {I}_{max} - {I}_{t h} ) + {I}_{t h} \qquad Equation 6$$

The calculation method for determining the average power corresponding to the small step duration t₀ is described below.

The continuous-mode average power P_{t0_cw} corresponding to Iₜ₀ is:

$${P}_{t 0 \_ cw} = {P}_{p \_ It 0}$$

Since the duration of the small step is to, it can be regarded as a pulse waveform output at a frequency f under a certain duty cycle, where the duty cycle is:

$${D}_{t 0} = {t}_{0} / T = {t}_{0} * f$$

Given that in PWM mode the average power of the laser output equals the peak power multiplied by the duty cycle, the average power of the small step is:

$${P}_{t 0} = {P}_{p \_ It 0} * {D}_{t 0} = {P}_{p \_ It 0} * ( {t}_{0} * f )$$

Since P_{p_It0} can be obtained by referencing Iₜ₀ and t₀ is determined through tuning, both are constants, and thus Pₜ₀ is also a constant.

Therefore, Equation 6 can be transformed into Equation 7 as follows:

$${I}_{out} = [ ( {P}_{out} - ( {P}_{p \_ It 0} * ( {t}_{0} * f ) ) - {P}_{aIth} ) / ( {P}_{pmax} * D - {P}_{aIth} ) ] * ( {I}_{max} - {I}_{th} ) + {I}_{th} \qquad Equation 7$$

In summary, the current control algorithm according to the embodiments of the present disclosure offers the following advantages:

The above-described current control algorithm, by introducing a “small-step current waveform,” effectively suppresses damage to optical components in the optical path caused by laser relaxation oscillations.

The “small-step current waveform” effectively reduces distortion in the pulse waveform of the effective current t₁, thereby enabling the laser output waveform to become more rectangular, and allowing the average laser power to more closely approximate the theoretically calculated value. With reduced pulse distortion, the Iₜₕ corresponding to different pulse frequencies under the same duty cycle exhibits a linear relationship. By statistically analyzing the data of Iₜₕ and frequency f, the equation Iₜₕ Af+B can be obtained. Accordingly, there is no need, as in the prior art, to record the Iₜₕ corresponding to each frequency at every duty cycle.

The mathematical relationship between the average output power of the laser terminal and the adjusted current is designed to incorporate the average power contribution of the small step, thereby enabling more accurate and precise adjustment of the output current to achieve the desired terminal average power.

FIG. 6 illustrates a schematic structural diagram of a laser current control apparatus for suppressing laser relaxation oscillations, provided in an embodiment of the present disclosure. The apparatus includes:
a waveform output module 601, configured to control a current signal having a predetermined waveform to be input into a laser drive circuit, wherein the predetermined waveform includes a first step and a second step, the amplitude of the first step is smaller than that of the second step, and the current signal corresponding to the first step induces a relaxation oscillation waveform whose amplitude is below a safety threshold; and
an adjustment module 602, configured to adjust the amplitude of the second step based on the relationship between the average laser output power and the drive current. The current signal of the second step, after being processed by the laser drive circuit, results in the drive current. The relationship between the average laser output power and the drive current is determined by the peak power corresponding to the first step, the duty cycle corresponding to the first step, the maximum drive current, the threshold current, the peak laser power corresponding to the maximum drive current, and the duty cycle corresponding to the second step.

Optionally, the relationship between the average laser output power and the drive current signal is as follows:

$${P}_{out} = {P}_{p \_ It 0} * ( {t}_{0} * f ) + [ ( {I}_{out} - {I}_{th} ) / ( {I}_{max} - {I}_{th} ) ] * ( {P}_{pmax} * D )$$

where Pₒᵤₜ is the average laser output power, P_{p_It0} is the peak power corresponding to the first step, to *f is the duty cycle corresponding to the first step, t₀ is the width of the first step, Iₒᵤₜ is the drive current, Iₘₐₓ is the maximum drive current, Iₜₕ is the threshold current, Pₚₘₐₓ is the peak laser power corresponding to the maximum drive current (i.e., the maximum peak laser power), and D is the duty cycle corresponding to the second step.

Optionally, the threshold current is linearly and positively correlated with the laser pulse frequency.

The present disclosure further provides a laser device, comprising a computer-readable storage medium storing a computer program and a processor. When the processor reads and executes the computer program, the above-described method for controlling laser current to suppress relaxation oscillations is implemented.

The laser current control apparatus and the laser device for suppressing laser relaxation oscillations provided in this embodiment can achieve the same technical effect as the above-described method. To avoid redundancy, detailed descriptions are omitted herein.

Although the present disclosure has been described with reference to the foregoing embodiments, it should not be construed as being limited thereto. Various modifications and changes may be made by those skilled in the art without departing from the spirit and scope of the present disclosure. Therefore, the protection scope of the present disclosure should be defined by the appended claims.

It should be further noted that the relational terms such as “first” and “second” used in this disclosure are merely for distinguishing one entity or operation from another and do not necessarily imply any actual relationship or order between such entities or operations. Moreover, the terms “comprise,” “include,” or any variations thereof are intended to cover non-exclusive inclusion, such that a process, method, article, or apparatus that comprises a list of elements is not limited to those elements but may include other elements not expressly listed or inherent to such process, method, article, or apparatus. Without further limitation, an element defined by the phrase “comprising a . . . ” does not exclude the presence of additional like elements in the process, method, article, or apparatus that comprises the element.

The embodiments disclosed herein are described in a progressive manner, with each embodiment focusing on aspects that differ from the others. Similar or identical parts between the embodiments can be referred to mutually. For the laser current control apparatus and laser device for suppressing laser relaxation oscillations disclosed in these embodiments, since they correspond to the above-described method, their descriptions are simplified, and reference may be made to the method section for related details.

The foregoing descriptions of the disclosed embodiments enable those skilled in the art to implement or use the present disclosure. Various modifications to these embodiments will be readily apparent to those skilled in the art, and the general principles defined herein may be applied to other embodiments without departing from the spirit or scope of the present disclosure. Accordingly, the present disclosure is not to be limited to the embodiments shown herein but is to be accorded the broadest scope consistent with the principles and novel features disclosed herein.

### INDUSTRIAL APPLICABILITY

The present disclosure provides a laser current control method, apparatus, and laser device for suppressing laser relaxation oscillations. By designing a small-step current waveform, the proposed solution effectively suppresses damage to optical components in the optical path caused by laser relaxation oscillations. The small-step current waveform significantly reduces waveform distortion in the effective current pulses, resulting in a more rectangular laser output waveform. This enables more accurate and precise modulation of the output current to achieve the desired terminal average power, thereby offering substantial economic benefits.

1. A laser current control method for suppressing laser relaxation oscillations, comprising:
controlling a current signal with a preset waveform to be input to a laser drive circuit;
wherein the preset waveform comprises a first step and a second step, an amplitude of the first step being smaller than an amplitude of the second step, and a laser relaxation oscillation waveform triggered by the current signal of the first step having an amplitude less than a safety threshold;
adjusting the amplitude of the second step based on a relationship between average laser output power and drive current;
wherein the current signal of the second step is processed by the laser drive circuit to obtain the drive current;
and the relationship between the average laser output power and the drive current is determined by a peak power corresponding to the first step, a duty cycle corresponding to the first step, a maximum drive current, a threshold current, a peak power corresponding to the maximum drive current, and a duty cycle corresponding to the second step, wherein the relationship between the average laser output power and the drive current signal is as follows:
$${P}_{out} = {P}_{p \_ It 0} * ( {t}_{0} * f ) + [ ( {I}_{out} - {I}_{th} ) / ( {I}_{max} - {I}_{th} ) ] * ( {P}_{pmax} * D )$$
wherein Pₒᵤₜ is the average laser output power; P_{p_It0} is the peak power corresponding to the first step; t₀*f is the duty cycle corresponding to the first step; t₀ is the width of the first step; Iₒᵤₜ is the drive current; Iₘₐₓ is the maximum drive current; Iₜₕ is the threshold current; Pₚₘₐₓ is the peak laser power corresponding to the maximum drive current; and D is the duty cycle corresponding to the second step,
wherein the threshold current is linearly and positively correlated with the laser pulse frequency,
wherein the relationship between the threshold current and the laser pulse frequency is as follows:
Iₜₕ=Af+B
wherein f is the laser pulse frequency, and A and B are coefficients.

2. The laser current control method for suppressing laser relaxation oscillations according to any one of claim 1, wherein the method further comprises:
tuning the amplitude and the width of the first step based on a tolerance value of components in the laser drive circuit.

3. The laser current control method for suppressing laser relaxation oscillations according to claim 1,
wherein the derivation process of the relationship between the average laser output power and the drive current signal is as follows:
$$since {P}_{pset} : {P}_{pmax} = ( {I}_{out} - {I}_{th} ) : ( {I}_{max} - {I}_{th} ) \qquad Equation$$
$$then {I}_{out} = ( {P}_{pset} / {P}_{pmax} ) * ( {I}_{max} - {I}_{th} ) + {I}_{th}$$
wherein Pₚₛₑₜ is the peak power;
the average laser output power Pₒᵤₜ is equal to an average power Pₜ₀ of the first step plus an average power P_{Iout} to be output, thus:
$${P}_{out} = {P}_{t 0} + {P}_{Iout} \qquad Equation$$
the average power P_{Iout} to be output is equal to a peak power Pₚₛₑₜ corresponding to Iₒᵤₜ multiplied by the duty cycle D, thus:
$${P}_{Iout} = {P}_{pset} * D 3 \qquad Equation$$
from Equations \textcircled{1} and \textcircled{3}, it follows that:
$${I}_{out} = [ {P}_{Iout} / ( {P}_{pmax} * D ) ] * ( {I}_{max} - {I}_{th} ) + {I}_{th} \qquad Equation$$
$${P}_{out} = {P}_{t 0} + [ ( {I}_{out} - {I}_{th} ) / ( {I}_{max} - {I}_{th} ) ] * ( {P}_{pmax} * D ) \qquad Equation$$
the average power P_{t0 _cw} in continuous mode corresponding to the current Iₜ₀ of the first step is:
$${P}_{t 0 \_ cw} = {P}_{p \_ It 0}$$
the width of the first step is to, and its duty cycle is:
$${D}_{t 0} = {t}_{0} * f$$
the average power of the first step is:
$${P}_{t 0} = {P}_{p \_ It 0} * {D}_{t 0} = {P}_{p \_ It 0} * ( {t}_{0} * f )$$
thus, Equation \textcircled{5} is transformed into:
$${P}_{out} = {P}_{p \_ It 0} * ( {t}_{0} * f ) + [ ( {I}_{out} - {I}_{th} ) / ( {I}_{max} - {I}_{th} ) ] * ( {P}_{pmax} * D ) \qquad Equation$$

4. A laser current control apparatus for suppressing laser relaxation oscillations, comprising:
a waveform output module configured to control a current signal with a preset waveform to be input to a laser drive circuit;
wherein the preset waveform comprises a first step and a second step, the amplitude of the first step being smaller than an amplitude of the second step, and a laser relaxation oscillation waveform triggered by the current signal of the first step having an amplitude less than a safety threshold;
a regulation module configured to adjust the amplitude of the second step based on the relationship between average laser output power and the drive current;
wherein the current signal of the second step is processed by the laser drive circuit to obtain the drive current; and
wherein the relationship between the average laser output power and the drive current is determined by a peak power corresponding to the first step, a duty cycle corresponding to the first step, the maximum drive current, the threshold current, the peak laser power corresponding to the maximum drive current, and the duty cycle corresponding to the second step,
wherein the relationship between the average laser output power and the drive current signal is as follows:
$${P}_{out} = {P}_{p \_ It 0} * ( {t}_{0} * f ) + [ ( {I}_{out} - {I}_{th} ) / ( {I}_{max} - {I}_{th} ) ] * ( {P}_{pmax} * D )$$
wherein Pₒᵤₜ is the average laser output power; P_{p_It0} is the peak power corresponding to the first step; t₀*f is the duty cycle corresponding to the first step; t₀ is the width of the first step; Lout is the drive current; Iₘₐₓ is the maximum drive current; In is the threshold current; Pₚₘₐₓ is the peak laser power corresponding to the maximum drive current; and D is the duty cycle corresponding to the second step,
wherein the threshold current is linearly and positively correlated with the laser pulse frequency,
wherein the relationship between the threshold current and the laser pulse frequency is as follows:
$${I}_{th} = Af + B$$
wherein f is the laser pulse frequency, and A and B are coefficients.

5. A laser device, comprising a computer-readable storage medium storing a computer program and a processor, wherein the computer program, when read and executed by the processor, is configured to implement the laser current control method for suppressing laser relaxation oscillations according to claim 1.
